(19) United States
(12) Patent Application Publication
(10) Pub. No.: US 2025/0293184 A1
(43) Pub. Date: Sep. 18, 2025

(54) CASCADED RADIO FREQUENCY SYSTEM IN A SINGLE MULTI-CHIP PACKAGE

(71) Applicant: Infineon Technologies AG, Neubiberg (DE)

(72) Inventors: Alexander Michael MELZER, Alberndorf in der Riedmark (AT); Faisal AHMED, Engerwitzdorf (AT)

(21) Appl. No.: 19/068,665

(22) Filed: Mar. 3, 2025

(30) Foreign Application Priority Data
Mar. 12, 2024 (DE) 102024202325.6

(51) Int. Cl. H01L 23/66; H01L 23/29; H01L 23/498; H01L 25/065; H01Q 1/22

(52) U.S. Cl. CPC H01L 23/66; H01L 23/293; H01L 23/49816; H01L 23/49827; H01L 25/0655; H01Q 1/2283; H01L 2223/6616; H01L 2223/6627; H01L 2223/6683

(57) ABSTRACT

A radio frequency (RF) device includes a primary RF chip and at least one secondary RF chip, wherein the primary RF chip and the at least one secondary RF chip form a cascaded RF system. The primary RF chip and the at least one secondary RF chip are collectively assembled in a single multi-chip package.

### CROSS-REFERENCE TO RELATED APPLICATION

This application claims priority to Germany Patent Application No. 102024202325.6 filed on Mar. 12, 2024, the content of which is incorporated by reference herein in its entirety.

### TECHNICAL FIELD

The present disclosure generally relates to radio frequency (RF) devices and methods for manufacturing thereof. More particularly, the present disclosure relates to a cascaded RF system assembled in a single multi-chip package.

### BACKGROUND

Single RF transceiver chips may only include a limited number of virtual array elements. In order to meet the requirements of certain applications, such as e.g., autonomous driving, it may therefore be necessary to cascade several such RF transceiver chips and synchronize them as a single unit. The cascading of multiple RF transceiver chips is usually carried out on printed circuit boards.

Manufacturers and developers of RF devices are constantly striving to improve their products. In the above context, it may be desirable to provide RF devices with improved performance, smaller size and reduced cost. In addition, it may be desirable to provide suitable methods for manufacturing such RF devices.

### SUMMARY

An aspect of the present disclosure relates to a radio frequency (RF) device. The RF device includes a primary RF chip and at least one secondary RF chip, wherein the primary RF chip and the at least one secondary RF chip form a cascaded RF system. The primary RF chip and the at least one secondary RF chip are collectively assembled in a single multi-chip package.

A further aspect of the present disclosure relates to a method for manufacturing an RF device. The method includes an act of collectively assembling a primary RF chip and at least one secondary RF chip in a single multi-chip package. The primary RF chip and the at least one secondary RF chip form a cascaded RF system.

### BRIEF DESCRIPTION OF THE DRAWINGS

Devices and methods in accordance with the disclosure are described in more detail below based on the drawings. The elements of the drawings are not necessarily to scale relative to each other. Similar reference numerals may designate corresponding similar parts.

The technical features of the various illustrated examples may be combined unless they exclude each other and/or can be selectively omitted if not described to be necessarily required.

FIG. 1 schematically illustrates a top view of an RF device 100 in accordance with the disclosure.

FIG. 2 schematically illustrates a top view of an RF device 200 in accordance with the disclosure.

FIG. 3 schematically illustrates a cross-sectional side view of an RF device 300 in accordance with the disclosure.

FIG. 4 schematically illustrates a cross-sectional side view of an RF device 400 in accordance with the disclosure.

FIG. 5 schematically illustrates a top view of an RF device 500 in accordance with the disclosure.

FIG. 6 schematically illustrates a top view of an RF device 600 in accordance with the disclosure.

FIG. 7 schematically illustrates a top view of an RF device 700 in accordance with the disclosure.

FIG. 8 illustrates a flowchart of a method for manufacturing an RF device in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, or the like may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

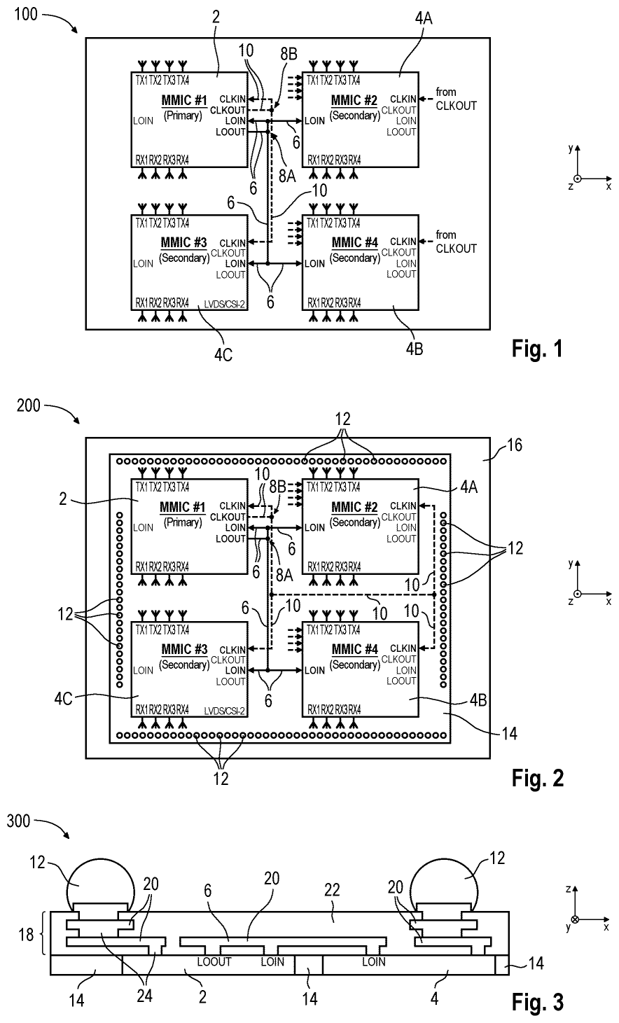

Referring now to FIG. 1, a radio frequency (RF) device 100 may include a primary RF chip 2 and at least one secondary RF chip 4. In the illustrated example, the RF device 100 may include an example and non-limiting number of three secondary RF chips 4A to 4C. In further examples, the number of secondary RF chips may vary and depend on the respective application. In some applications, the RF device 100 may include one primary RF chip 2 and one secondary RF chip 4. Accordingly, while examples explained below may show three secondary RF chips 4A to 4C, other examples may include one, two, or more than three secondary RF chips 4A to 4C with the same benefits. While examples may refer to secondary RF chips 4A to 4C it is to be regarded to disclose concurrently examples in which instead of three secondary RF chips 4A to 4A at least one secondary RF chip 4 is provided in the multi-chip package. Accordingly, throughout the disclosure the secondary RF chips 4A to 4C can be replaced by the term at least one secondary RF chip 4. The primary RF chip 2 and the at least one secondary RF chip 4 may form a cascaded RF system. The primary RF chip 2 and the at least one secondary RF chip 4 may be collectively assembled in a single multi-chip package. In the example of FIG. 1, a collective assembly of the RF chips is indicated by a rectangle surrounding the RF chips.

A multi-chip package may be seen as a collective assembly of multiple separate chips (semiconductor dies) and other optional electronic components. In examples, the multiple RF chips 2 and 4 are not individually packaged, but are packaged together by the multi-chip package to form a single semiconductor package for the multiple chips. In some examples, molding the multiple chips together and forming redistributions may be part of the forming of a multi-chip package. In some examples, the multiple chips may include multiple MMIC (Monolithic Microwave Integrated Circuit) semiconductor chips. Package types may be defined by international, national, or industrial standards, but may also be specific to an individual manufacturer. A package may provide means for connecting the package to its external environment (e.g., a printed circuit board (PCB)) via suitable electrical connection elements (e.g., leads, pads, balls, pins, or the like). Accordingly, the multi-chip package of FIG. 1 may include at least one external connection element (not illustrated) configured to mechanically and electrically couple the multi-chip package to e.g., a PCB (not illustrated). Example external connection elements are shown and discussed in connection with FIG. 2. In addition, a package may optionally provide means for protecting its components against threats, such as e.g., mechanical impact, chemical contamination, moisture, light exposure, or the like. In this regard, the multi-chip package of FIG. 1 may include a chip package housing, wherein the primary RF chip 2 and the secondary RF chips 4A to 4C may be encapsulated in the chip package housing. An example chip package housing is shown and discussed in connection with FIG. 2.

As can be seen from the example top view of FIG. 1, a main surface of the primary RF chip 2 and main surfaces of the secondary RF chips 4A to 4C may be arranged in the x-y-plane. Accordingly, the primary RF chip 2 and the secondary RF chips 4A to 4C may be separated in a lateral direction, the lateral direction being parallel to the main surfaces of the RF chips 2 and 4. That is, when viewed in the z-direction, the footprints of the RF chips 2 and 4 may be laterally displaced and/or may not overlap. The RF chips 2 and 4 may be arranged at a substantially similar height with respect to the z-direction. In examples, the multiple RF chips 2 and 4 are not stacked over each other in the z-direction.

In the top view of FIG. 1, a footprint area of the RF device 100 (or more particular of the multi-chip package) may be smaller than about 10 cm² or about 9 cm² or about 8 cm² or about 7 cm² or about 6 cm² or about 5 cm². In an example, but non-limiting case, side lengths of the RF device 100 (or more particular of the multi-chip package) in the x-direction and in the y-direction may be in a range between about 10 mm to about 15 mm, respectively.

In the following, features of the primary RF chip 2 are specified. It is to be noted that each of the secondary RF chips 4A to 4C may include some or all features of the RF chip 2. The primary RF chip 2 may be made of or may include an arbitrary semiconductor material, such as e.g., silicon. The primary RF chip 2 (or electronic circuits thereof) may be configured to operate in a frequency range of greater than about 1 GHz, in some examples greater than about 10 GHz. The primary RF chip 2 may thus also be referred to as radio frequency chip or high frequency chip or microwave frequency chip. More particular, the primary RF chip 2 may be configured to operate in an RF range or microwave frequency range, which may range from about 1 GHz to about 1 THz, more particular from about 10 GHz to about 300 GHz. Microwave circuits may include, for example, microwave transmitters, microwave receivers, microwave transceivers, microwave sensors, microwave detectors, or the like. RF devices in accordance with the disclosure may be used for radar applications in which the frequency of the RF signals may be modulated. The primary RF chip 2 may thus also be referred to as radar chip. In particular, the primary RF chip 2 may include or may correspond to an MMIC (Monolithic Microwave Integrated Circuit).

Radar microwave devices may e.g., be used in automotive, industrial, military and/or defense applications for range and speed measuring systems. For example, automotive applications may include advanced driver assistant systems, automatic vehicle cruise control systems, vehicle anti-collision systems, or the like. Such systems may operate in the microwave frequency range and may utilize FMCW (Frequency Modulation Continuous Wave) signals, for example in the 24 GHz, 76 GHz, or 79 GHz frequency bands. A use of radar microwave systems may provide constant and efficient driving of vehicles. An efficient driving style may, for example, reduce fuel consumption such that CO₂ emission may be reduced and energy savings may be enabled. In addition, abrasion of vehicle tires, brake discs and brake pads may be reduced, thereby reducing fine dust pollution. Improved RF or radar systems, as specified herein, may thus contribute to green technology solutions, e.g., climate-friendly solutions providing reduced energy usage.

The primary RF chip 2 may include as an example a number of four transmit (TX) channels TX1 to TX4 configured to transmit RF signals to an antenna. In addition, the primary RF chip 2 may include as an example a number of four receive channels RX1 to RX4 configured to receive RF signals. The primary RF chip 2 may thus be referred to as transceiver TRX chip. The respective antennas to transmit and receive the RF signals may be integrated in the multi-chip package or may be arranged outside of the multi-chip package and coupled to RF ports arranged in the multi-chip package. In further examples, the number of TX antennas and RX antennas of the primary RF chip 2 may differ, such as e.g., three TX antennas and four RX antennas.

The primary RF chip 2 and the secondary RF chips 4A to 4C may be interconnected and cascaded to form a cascaded RF system. Cascading multiple transceiver RF chips may enhance the number of transmit and receive channels and may therefore increase a number of virtual antenna array elements, thereby improving target detection and target resolution which may be required by certain applications, such as e.g., L4 and L5 autonomous driving. The RF chips 2 and 4 may be synchronized in order to make the cascaded RF system operate as a single RF system in which each of the RF channels has a predefined phase relation to each other. For achieving appropriate synchronization between different RF chips, specific signals may be shared between the primary RF chip 2 and the secondary RF chips 4A to 4C. In this context, the primary RF chip 2 may be configured to generate a local oscillator (LO) signal which may be shared across all RF chips in the entire cascaded RF system. In other words, the secondary RF chips 4A to 4C will use the LO signal generated by the primary RF chip for operations such as transmitting signals or mixing with received signals rather than generating and using an unsynchronized LO signal on their own. The LO signal may be a mm-wave LO signal. In some applications, the LO signal may be an FMCW-signal including a plurality of frequency ramps. In addition, the primary RF chip 2 may be configured to generate a clock signal (e.g., generated by a crystal included in the primary RF chip 2) and share it with the secondary RF chips 4A to 4C. Sharing the clock signal may eliminate the need for additional crystals in the secondary RF chips 4A to 4C and may ensure that the cascaded system operates from a single clock source. The clock signal may also be referred to as system clock.

Cascading the RF chips 2 and 4 in a multi-chip package may allow reducing impacts on the distribution of the synchronization LO signal from the primary RF chip 2 to each secondary RF chip 4A to 4C as the length of the RF interconnection between the two RF chips can be made very short in a multi-chip package. When temperature changes, the length of the interconnection may also change which may cause phase variations of the LO signal distributed for synchronization from the primary RF chip 2 to each secondary RF chip 4A to 4C. For high resolution radar applications, such phase variations are undesired as they may change the phase relation between the respective RF channels. Arranging the primary RF chip 2 and the secondary RF chips 4A to 4C in a multi-chip package may allow significant reductions of phase variations due to temperature effects, thereby achieving an improved phase stability over temperature compared to conventional cascaded systems. In addition, RF losses can be minimized. In conventional systems, the LO signal may be frequency-divided prior to the distribution. Distinguished therefrom, examples disclosed herein may distribute the LO signal for synchronization without a frequency division. Furthermore, the lateral separation of the RF chips may allow designing the RF interconnection with less effort and complexity as for example for vertical stacked RF chips, since RF signals in the mm-wave range or above may require waveguides, strip-lines or other wave-elements which may be much easier to realize in a lateral direction.

The primary RF chip 2 may include multiple RF inputs and multiple RF outputs. In particular, the primary RF chip 2 may include at least one RF output LOOUT configured to output the LO signal and at least one RF input LOIN configured to input the LO signal. In addition, the primary RF chip 2 may include at least one RF output CLKOUT configured to output the clock signal and at least one RF input CLKIN configured to input the clock signal. Each of the secondary RF chips 4A to 4C may include similar RF inputs and RF outputs, but may not necessarily use all of them during operation. In the illustrated example, inputs and outputs required for an operation of the cascaded RF system are written in bold letters. For example, each of the secondary chips 4A to 4C may require the inputs LOIN and CLKIN, while the outputs LOOUT and CLKOUT are optional.

The RF device 100 may include an RF transmission interconnection 6 interconnecting the primary RF chip 2 and the secondary RF chips 4A to 4C. The RF transmission interconnection 6 may be configured to transmit the LO signal generated by the primary RF chip 2 from the primary RF chip 2 to the secondary RF chips 4A to 4C. In particular, the RF transmission interconnection 6 may be arranged in the multi-chip package. As can be seen from the top view of FIG. 1, the RF transmission interconnection 6 may be arranged between the RF chips 2 and 4.

The RF transmission interconnection 6 may include a first self-feeding connection arranged external to the primary RF chip 2. The first self-feeding connection may be configured to transmit the LO signal from the RF output LOOUT of the primary RF chip 2 to the RF input LOIN of the primary RF chip 2. The RF transmission interconnection 6 may include a first star point 8A. A star point may include one input and at least two outputs. The first star point 8A may be configured to provide the LO signal from the first star point 8A to the primary RF chip 2 (more particular to its input LOIN) and to the secondary RF chips 4A to 4C (more particular to the respective input LOIN). A distance between the first star point 8A and the primary RF chip 2 and distances between the first star point 8A and each of the secondary RF chips 4A and 4B may be substantially equivalent. It is to be noted that the distances may differ in FIG. 1 due to the qualitative character of the illustration.

Due to the equivalent distances each of the RF chips 2 and 4 may receive a same LO signal from the first star point 8A such that an operation of all RF chips 2 and 4 may be based on the same LO signal. In particular, the same LO signal may be received at the RF inputs LOIN of the RF chips 2 and 4 with a same phase such that coherence between all RF chips 2 and 4 may be provided. For example, it may thus be possible for all RX channels to convert down received signals with the same phase from RF to baseband. In order to guarantee coherence between the primary RF chip 2 and the secondary RF chips 4A to 4C, the primary RF chip 2 may feed the LO signal into itself via an external loop including the first star point 8A (instead of via an internal loop). Furthermore, as the length of the LO signal distribution is the same for each RF chip (including the primary RF chip 2 using the self-feed signal for operation), temperature effects affect each RF chip in the same manner, thereby reducing phase variations due to temperature variations.

The RF device 100 may include a clock interconnection 10 interconnecting the primary RF chip 2 and the secondary RF chips 4A to 4C. The clock interconnection 10 may be configured to transmit or share the clock signal between the primary RF chip 2 and the secondary RF chips 4A to 4C. In particular, the clock interconnection 10 may be arranged in the multi-chip package. As can be seen from the top view of FIG. 1, the clock interconnection 10 may be arranged between the RF chips 2 and 4.

The clock interconnection 10 may include a second self-feeding connection arranged external to the primary RF chip 2. The second self-feeding connection may be configured to transmit the clock signal from the clock output CLKOUT of the primary RF chip 2 to the clock input CLKIN of the primary RF chip 2. The clock interconnection 10 may include a second star point 8B configured to provide the clock signal from the second star point 8B to the primary RF chip 2 (more particular to its input CLKIN) and to the secondary RF chips 4A to 4C (more particular to the respective input CLKIN). A distance between the second star point 8B and the primary RF chip 2 and distances between the second star point 8B and each of the secondary RF chips 4A to 4C may be equivalent. It is to be noted that the distances may differ in FIG. 1 due to the qualitative character of the illustration. Due to the second self-feeding connection and the second star point 8B, an operation of all RF chips 2 and 4 may be based on the same clock signal or system clock.

It is to be noted that the RF device 100 and each of the RF chips 2 and 4 may include additional electronic circuitry, e.g., for processing transmit and/or receive RF signals in an analog and/or digital domain. For the sake of simplicity, such additional electronic circuitry is not explicitly shown and discussed in connection with the example of FIG. 1.

The RF device 200 of FIG. 2 may include some or all features of the RF device 100 of FIG. 1. The RF device 200 (or more particular the multi-chip package) may include multiple external connection elements 12 and a chip package housing 14. The external connection elements 12 may be configured to mechanically and electrically couple the multi-chip package to a PCB 16. The PCB 16 may be seen as a part of the RF device 200 or not. Since the RF transmission interconnection 6 and the clock interconnection 10 may be arranged in the multi-chip package, the PCB 16 may be free of any signal transmission structures for transmitting RF signals. In the illustrated example, the external connection elements 12 may include or may correspond to solder balls, copper pillar bumps, or the like. It is to be noted that the external connection elements 12 may be arranged on a main surface of the multi-chip package facing the PCB 16 and may thus not be visible in practice in the top view of FIG. 2.

The primary RF chip 2 and the secondary RF chips 4A to 4C may be at least partially encapsulated in the chip package housing 14. The chip package housing 14 may include or may be made of at least one of an epoxy, a filled epoxy, a glass fiber filled epoxy, an imide, a thermoplast, a thermoset polymer, a polymer blend, a laminate, a mold compound, glass, or the like. Various techniques may be used for encapsulating components of the RF device 200 in the chip package housing 14, for example at least one of compression molding, injection molding, powder molding, liquid molding, map molding, laminating, or the like.

The RF device 300 of FIG. 3 may include some or all features of previously described RF devices in accordance with the disclosure. The RF device 300 (or more particular the multi-chip package) may include an electrical redistribution layer (or electrical redistribution structure) 18. The electrical redistribution layer 18 may have one or more metal layers (or metal tracks) 20, which may extend substantially parallel to the main surfaces of the RF chips 2, 4 and the chip package housing 14. In the illustrated example, the main surfaces of the RF chips 2, 4 and the main surface of the chip package housing 14 may be coplanar and may form a common planar surface. The metal layers 20 may e.g., be made of copper or a copper alloy. One or more dielectric layers 22 may be arranged between the metal layers 20 to electrically isolate the metal layers 20 from one another. For example, the dielectric layers 22 may be made of at least one of an oxide or a nitride. Furthermore, metal layers 20 arranged on different vertical levels may be electrically connected to each other by one or more via connections 24. It is to be noted that the number of illustrated metal layers 20 and dielectric layers 22 is example and may differ in further examples.

The electrical redistribution layer 18 may be configured to provide an electrical connection between at least one of the RF chips 2, 4 and the external connection elements 12. The electrical redistribution layer 18 may at least partially extend over the upper main surface of the chip package housing 14. Accordingly, at least one of the external connection elements 12 may be laterally displaced to the RF chips 2 and 4. When viewed in the z-direction, at least one of the external connection elements 12 may be arranged outside of the footprints of the RF chips 2 and 4. In such case, the RF device 300 may be referred to as a fan-out device or a fan-out package. The area located outside of the chip footprints may be referred to as fan-out area. In the example of FIG. 3, the RF device 300 (or more particular the multi-chip package) may correspond to or may include an eWLB (embedded Wafer Level Ball Grid Array) package, e.g., a wafer level package manufactured based on an eWLB (embedded Wafer Level Ball Grid Array) process. In the case shown, the multi-chip package may correspond to a flip-chip package.

Referring back to the example of FIG. 1, at least one of the RF transmission interconnection 6 or the clock interconnection 10 may be formed in the electrical redistribution layer 18. In the example of FIG. 3, only the RF transmission interconnection 6 is illustrated while a clock interconnection is not shown for the sake of simplicity. At least one of the RF transmission interconnection 6 or the clock interconnection may include at least one of a microstrip line (e.g., a microstrip based single ended or differential line), a coplanar waveguide, a slot line, or the like. The transmission lines may e.g., be formed by the metal layers 20 and the dielectric layers 22 of the electrical redistribution layer 18.

Referring back to the example of FIG. 1, one or more of the TX antennas and RX antennas may be arranged or formed in the electrical redistribution layer 18. The antennas may be electrically coupled to a respective RF chip in the multi-chip package. One or more of the antennas may include at least one of a planar antenna (such as e.g., a dipole antenna, a bowtie antenna, a rhombus antenna, or the like) or a slot antenna (e.g., fed using a coplanar waveguide line). In particular, the antennas may be formed by the metal layers 20 of the electrical redistribution layer 18. One or more of the antennas may be arranged in a fan-out area of the electrical redistribution layer 18. The antennas may particularly be configured to receive and/or transmit RF signals in the z-direction.

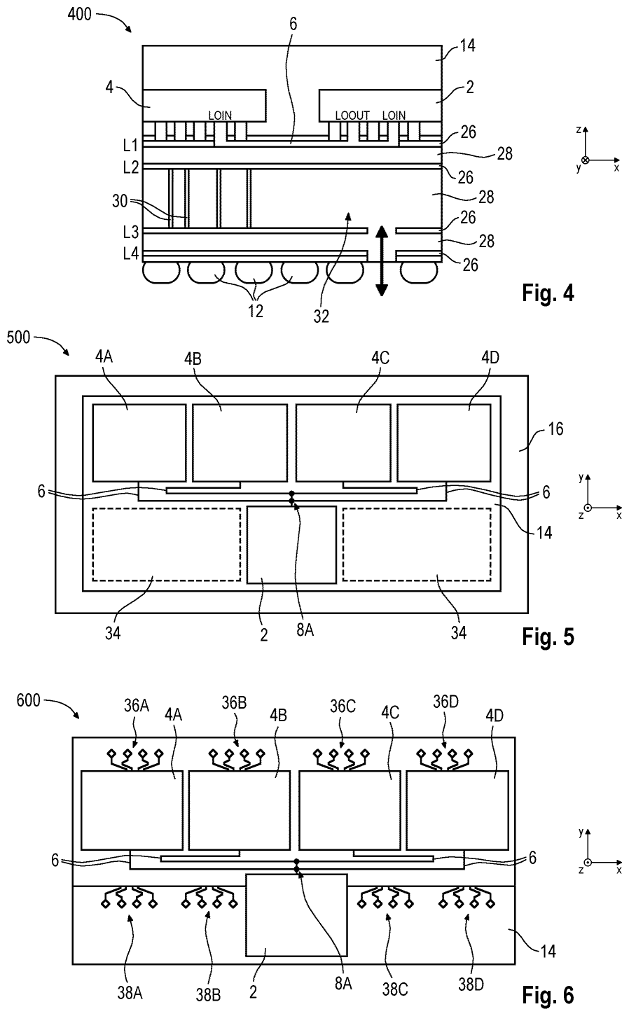

The RF device 400 of FIG. 4 may include some or all features of previously described RF devices in accordance with the disclosure. In the illustrated example, the RF device 400 may correspond to or may include a flip-chip package, but is not restricted thereto. The RF device 400 may include multiple metal layers (see L1 to L4) 26 arranged over (or under) the RF chips 2, 4 and the chip package housing 14. The primary RF chip 2 may be electrically connected to at least one of the secondary RF chips 4 via the metal layer L1. In the example of FIG. 4, the RF transmission interconnection 6 may be at least partially arranged in the metal layer L1. Furthermore, the RF device 400 may include multiple dielectric layers 28 arranged between the multiple metal layers 26. The metal layers 26 and the dielectric layers 28 may substantially extend in a direction parallel to the main surfaces of the RF chips 2 and 4. The metal layers L2 and L3 may be electrically connected in the vertical direction via multiple via connections 30. Optionally, similar via connections may provide an electrical connection in the vertical direction between the layers L1 and L2 and between the layers L3 and L4.

The RF device 400 may include at least one substrate integrated waveguide (SIW) 32 that may be configured for transmitting mm-wave signals in particular. Referring back to the example of FIG. 1, at least one of the RF transmission interconnection 6 or the clock interconnection 10 may include such SIW. The SIW 32 may include the metal layers L2 and L3 as well as the dielectric layer 28 arranged between the metal layers L2 and L3. In addition, the SIW 32 may include the plurality of via connections 30 extending between the metal layers L2 and L3. The via connections 30 may be arranged to form a via fence. The SIW 32 may be formed by the dielectric layer 28 covered on both faces by the metal layers L2 and L3. The dielectric layer 28 may embed the via connections 30 that may form two parallel rows of metallic via holes delimiting a propagation area of RF signals (e.g., electromagnetic waves) that are to be transmitted via the SIW 32. The propagating electromagnetic waves may be confined within the dielectric layer 28 by the metal layers L2 and L3 on each of the two surfaces of the dielectric layer 28 as well as between the two rows of metallic vias 30 connecting the metal layers L2 and L3. In the illustrated example, the SIW 32 may be configured to transmit electromagnetic waves in a lateral direction, e.g., in the x-y-plane.

The RF device 400 (or more particular the multi-chip package) may include an AFIP (Antenna Feed In Package). The AFIP may include a first launcher structure coupled to a first RF port of the primary RF chip 2 to transfer an RF signal between the first RF port and a waveguide antenna. In addition, the AFIP may include a second launcher structure coupled to a second RF port of the secondary RF chip 4 to transfer an RF signal between the second RF port and the waveguide antenna.

A launcher structure of the RF device 400 may be configured to couple a signal from the SIW 32 into a waveguide (such as e.g., an air-filled waveguide) external to the multi-chip package and/or from the external waveguide into the SIW 32. The launcher structure may include at least one coupling element that may e.g., be formed in the metal layer L3. For example, the coupling element may include or may correspond to one or multiple antennas, such as e.g., patch antennas. In the illustrated example, a launcher structure may be arranged substantially at the right end of the SIW 32. A coupling of RF signals from the SIW 32 into an external waveguide and vice versa is exemplarily indicated by a bidirectional arrow.

The RF device 500 of FIG. 5 may include some or all features of previously described RF devices in accordance with the disclosure. The RF device 500 may exemplarily include one primary RF chip 2 and four secondary RF chips 4A to 4D. Compared to the examples of FIGS. 1 and 2, the RF chips 2 and 4 may be arranged in a different fashion. The primary RF chip 2 may be configured to generate an LO signal and share the generated LO signal with the secondary RF chips 4A to 4D. As can be seen from the top view of FIG. 5, the chosen arrangement of the RF chips 2 and 4 may provide fan-out areas 34 arranged to the left and to the right of the primary RF chip 2 (see dashed rectangles). The RF device 500 may include one or more antennas that may be arranged in one or both of the fan-out areas 34 as previously described in connection with the example of FIG. 3.

The RF device 600 of FIG. 6 may include some or all features of previously described RF devices in accordance with the disclosure. Referring back to the example of FIG. 1, each of the secondary RF chips 4A to 4D may include multiple TX antennas 36A to 36D and multiple RX antennas 38A to 38D, respectively. In the illustrated example, the primary RF chip 2 may not necessarily be used for transmitting and receiving RF signals, but may particularly be used for generating at least one of an LO signal or a clock signal and sharing the signal(s) with the secondary RF chips 4A to 4D. Referring back to the example of FIG. 5, the RX antennas 38A to 38B may be particularly arranged in the fan-out areas 34.

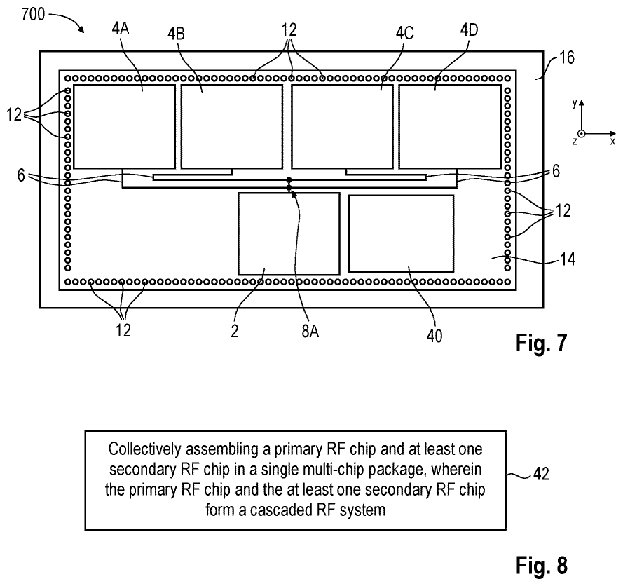

The RF device 700 of FIG. 7 may include some or all features of previously described RF devices in accordance with the disclosure. The RF device 700 may include a microcontroller chip 40 configured to process signals transmitted to and/or received from at least one of the primary RF chip 2 and the secondary RF chips 4A to 4D. The microcontroller chip 40 may be arranged in the multi-chip package. Referring back to the examples of FIGS. 3 and 4, the microcontroller chip 40 may e.g., be embedded in the chip package housing 14 laterally displaced to the RF chips 2 and 4. In the example of FIG. 7, electrical connections between the microcontroller chip 40 and the RF chips 2 and 4 are not shown for the sake of simplicity.

FIG. 8 illustrates a flowchart of a method for manufacturing an RF device in accordance with the disclosure. The method may be used for manufacturing RF devices as previously discussed and may thus be read in connection with any of the foregoing figures. The method of FIG. 8 is described in a general manner in order to qualitatively specify aspects of the disclosure. It is to be understood that the method may include further aspects. For example, the method may be extended by any of the aspects described in connection with other examples in accordance with the disclosure.

At 42, a primary RF chip and at least one secondary RF chip may be collectively assembled in a single multi-chip package. The primary RF chip and the at least one secondary RF chip may form a cascaded RF system.

RF devices in accordance with the disclosure may provide the following technical effects and may outperform conventional devices in various aspects.

In conventional RF systems, cascading RF chips may be carried out on PCBs. In contrast to this, RF devices as described herein may be cascaded in a package (e.g., in a backend process) and may provide significantly smaller sizes. For example, a footprint area of the described multi-chip packages may be smaller than about 10 cm².

Since the RF transmission interconnection and/or the clock interconnection of a respective RF device may be arranged in the multi-chip package, a PCB for mounting the package may be free of any signal transmission structures for transmitting RF signals. Such PCBs may be less expensive compared to PCBs including RF transmission structures.

Due to the package internal arrangement of the RF transmission interconnection and/or the clock interconnection, chip-to-package losses for each LO signal input/output interface may be avoided. The package internal LO signal distribution may suffer from lower losses compared to the conventional PCB solutions where the LO signals may need to be distributed over a larger area of the PCB.

RF devices in accordance with the disclosure may include fan-out areas configured to provide suitable space for antennas of the multi-chip package.

### ASPECTS

In the following, RF devices and methods for manufacturing such RF devices are explained using the following aspects.

Aspect 1 is an RF device, comprising: a primary RF chip; and at least one secondary RF chip, wherein the primary RF chip and the at least one secondary RF chip form a cascaded RF system, and wherein the primary RF chip and the at least one secondary RF chip are collectively assembled in a single multi-chip package.

Aspect 2 is an RF device according to Aspect 1, wherein the multi-chip package comprises at least one external connection element configured to mechanically and electrically couple the multi-chip package to a printed circuit board.

Aspect 3 is an RF device according to Aspect 1 or 2, wherein the multi-chip package comprises a chip package housing, wherein the primary RF chip and the at least one secondary RF chip are encapsulated in the chip package housing.

Aspect 4 is an RF device according to Aspect 3, wherein the chip package housing comprises a mold compound.

Aspect 5 is an RF device according to one of the preceding Aspects, wherein the primary RF chip and the at least one secondary RF chip are separated in a lateral direction, the lateral direction being parallel to a main surface of the primary RF chip and a main surface of the at least one secondary RF chip.

Aspect 6 is an RF device according to one of the preceding Aspects, further comprising: an RF transmission interconnection configured to transmit a local oscillator signal generated by the primary RF chip from the primary RF chip to each secondary RF chip of the at least one secondary RF chip, wherein the RF transmission interconnection is arranged in the multi-chip package.

Aspect 7 is an RF device according to one of the preceding Aspects, further comprising: a clock interconnection configured to transmit a clock signal between the primary RF chip and each secondary RF chip of the at least one secondary RF chip, wherein the clock interconnection is arranged in the multi-chip package.

Aspect 8 is an RF device according to Aspect 2 and Aspect 6 and/or 7, wherein the multi-chip package comprises an electrical redistribution layer configured to provide an electrical connection between at least one of the RF chips (e.g., primary RF chip and/or the at least one secondary RF chip) and the at least one external connection element, wherein at least one of the RF transmission interconnection or the clock interconnection is formed in the electrical redistribution layer.

Aspect 9 is an RF device according to one or more of Aspects 6 to 8, wherein at least one of the RF transmission interconnection or the clock interconnection comprises at least one of a microstrip line, a coplanar waveguide, or a slot line.

Aspect 10 is an RF device according to one or more of Aspects 6 to 9, wherein at least one of the RF transmission interconnection or the clock interconnection comprises a substrate integrated waveguide.

Aspect 11 is an RF device according to one or more of Aspects 6 to 10, wherein: the RF transmission interconnection comprises a first self-feeding connection arranged external to the primary RF chip, wherein the first self-feeding connection is configured to transmit the local oscillator signal from an RF output of the primary RF chip to an RF input of the primary RF chip, and/or the clock interconnection comprises a second self-feeding connection arranged external to the primary RF chip, wherein the second self-feeding connection is configured to transmit the clock signal from a clock output of the primary RF chip to a clock input of the primary RF chip.

Aspect 12 is an RF device according to one or more of Aspects 6 to 11, wherein: the RF transmission interconnection comprises a first star point configured to provide the local oscillator signal from the first star point to the primary RF chip and to the at least one secondary RF chip, and/or the clock interconnection comprises a second star point configured to provide the clock signal from the second star point to the primary RF chip and to the at least one secondary RF chip.

Aspect 13 is an RF device according to Aspect 12, wherein: a distance between the first star point and the primary RF chip and distances between the first star point and each of the at least one secondary RF chip are equivalent, and/or a distance between the second star point and the primary RF chip and distances between the second star point and each of the at least one secondary RF chip are equivalent.

Aspect 14 is an RF device according to one of Aspects 8 to 13, wherein the multi-chip package comprises at least one antenna electrically coupled to at least one of the RF chips (e.g., primary RF chip and/or the at least one secondary RF chip), wherein the at least one antenna is arranged in the electrical redistribution layer.

Aspect 15 is an RF device according to Aspect 14, wherein the at least one antenna is arranged in a fan-out area of the electrical redistribution layer.

Aspect 16 is an RF device according to Aspect 14 or 15, wherein the at least one antenna comprises at least one of a planar antenna or a slot antenna.

Aspect 17 is an RF device according to one of the preceding Aspects, further comprising: a printed circuit board, wherein the multi-chip package is mounted on the printed circuit board, wherein the printed circuit board is free of any signal transmission structures for transmitting RF signals.

Aspect 18 is an RF device according to one of the preceding Aspects, further comprising: a microcontroller chip configured to process signals transmitted to and/or received from the primary RF chip and the at least one secondary RF chip, wherein the microcontroller chip is arranged in the multi-chip package.

Aspect 19 is an RF device according to one of the preceding Aspects, wherein a footprint area of the multi-chip package is smaller than 10 cm².

Aspect 20 is an RF device according to one of the preceding Aspects, wherein each of the primary RF chip and the at least one secondary RF chip comprises a transceiver MMIC (Monolithic Microwave Integrated Circuit).

Aspect 21 is an RF device according to one of the preceding Aspects, wherein the multi-chip package comprises an eWLB (embedded Wafer Level Ball Grid Array) package.

Aspect 22 is an RF device according to one of the preceding Aspects, wherein the multi-chip package comprises an AFIP (Antenna Feed In Package).

Aspect 23 is an RF device according to Aspect 22, wherein: the AFIP comprises a first launcher structure coupled to a first RF port of the primary RF chip to transfer a first RF signal between the first RF port and a waveguide antenna, and the AFIP comprises a second launcher structure coupled to a second RF port of the secondary RF chip to transfer a second RF signal between the second RF port and the waveguide antenna.

Aspect 24 is a method for manufacturing an RF device, the method comprising: collectively assembling a primary RF chip and at least one secondary RF chip in a single multi-chip package, wherein the primary RF chip and the at least one secondary RF chip form a cascaded RF system.

As employed in this specification, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the words “over” and “on” used with regard to e.g., a material layer formed or located “over” or “on” a surface of an object may be used herein to mean that the material layer may be located (e.g., formed, deposited, or the like) “directly on”, e.g., in direct contact with, the implied surface. The words “over” and “on” used with regard to e.g., a material layer formed or located “over” or “on” a surface may also be used herein to mean that the material layer may be located (e.g., formed, deposited, or the like) “indirectly on” the implied surface with e.g., one or multiple additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the words “example” and “example” are used herein to mean serving as an example, instance, or illustration. Any aspect or design described herein as “example” or “example” is not necessarily to be construed as advantageous over other aspects or designs. Rather, use of the words “example” and “example” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures.

Although the disclosure has been shown and described with respect to one or multiple implementations, equivalent alterations and modifications will occur to others skilled in the art based at least in part upon a reading and understanding of this specification and the annexed drawings. The disclosure includes all such modifications and alterations and is limited only by the concept of the following claims. In particular regard to the various functions performed by the above described components (e.g., elements, resources, or the like), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or multiple other features of the other implementations as may be desired and advantageous for any given or particular application.

1. A radio frequency (RF) device, comprising:
a primary RF chip; and
at least one secondary RF chip,
wherein the primary RF chip and the at least one secondary RF chip form a cascaded RF system, and
wherein the primary RF chip and the at least one secondary RF chip are collectively assembled in a single multi-chip package.

2. The RF device of claim 1, wherein the single multi-chip package comprises at least one external connection element configured to mechanically and electrically couple the single multi-chip package to a printed circuit board.

3. The RF device of claim 1, wherein the single multi-chip package comprises a chip package housing, and
wherein the primary RF chip and the at least one secondary RF chip are encapsulated in the chip package housing.

4. The RF device of claim 3, wherein the chip package housing comprises a mold compound.

5. The RF device of claim 1, wherein the primary RF chip and the at least one secondary RF chip are separated in a lateral direction, the lateral direction being parallel to a main surface of the primary RF chip and a main surface of the at least one secondary RF chip.

6. The RF device of claim 1, further comprising:
an RF transmission interconnection configured to transmit a local oscillator signal generated by the primary RF chip from the primary RF chip to each secondary RF chip of the at least one secondary RF chip,
wherein the RF transmission interconnection is arranged in the single multi-chip package.

7. The RF device of claim 1, further comprising:
a clock interconnection configured to transmit a clock signal between the primary RF chip and each secondary RF chip of the at least one secondary RF chip,
wherein the clock interconnection is arranged in the single multi-chip package.

8. The RF device of claim 6, further comprising:
a clock interconnection configured to transmit a clock signal between the primary RF chip and each secondary RF chip of the at least one secondary RF chip.
wherein the clock interconnection is arranged in the single multi-chip package,
wherein the single multi-chip package comprises at least one external connection element configured to mechanically and electrically couple the single multi-chip package to a printed circuit board,
wherein the single multi-chip package comprises an electrical redistribution layer configured to provide an electrical connection between at least one of the primary RF chip or the at least one secondary RF chip and the at least one external connection element, and
wherein at least one of the RF transmission interconnection or the clock interconnection is formed in the electrical redistribution layer.

9. The RF device of claim 8, wherein at least one of the RF transmission interconnection or the clock interconnection comprises at least one of a microstrip line, a coplanar waveguide, or a slot line.

10. The RF device of claim 8, wherein at least one of the RF transmission interconnection or the clock interconnection comprises a substrate integrated waveguide.

11. The RF device of claim 6, further comprising:
a clock interconnection configured to transmit a clock signal between the primary RF chip and each secondary RF chip of the at least one secondary RF chip,
wherein the clock interconnection is arranged in the single multi-chip package, and
wherein the RF transmission interconnection comprises a first self-feeding connection arranged external to the primary RF chip, wherein the first self-feeding connection is configured to transmit the local oscillator signal from an RF output of the primary RF chip to an RF input of the primary RF chip, and
wherein the clock interconnection comprises a second self-feeding connection arranged external to the primary RF chip, wherein the second self-feeding connection is configured to transmit the clock signal from a clock output of the primary RF chip to a clock input of the primary RF chip.

12. The RF device of claim 6, further comprising:
a clock interconnection configured to transmit a clock signal between the primary RF chip and each secondary RF chip of the at least one secondary RF chip,
wherein the clock interconnection is arranged in the single multi-chip package, and
wherein the RF transmission interconnection comprises a first star point configured to provide the local oscillator signal from the first star point to the primary RF chip and to the at least one secondary RF chip, and
wherein the clock interconnection comprises a second star point configured to provide the clock signal from the second star point to the primary RF chip and to the at least one secondary RF chip.

13. The RF device of claim 12, wherein:
a distance between the first star point and the primary RF chip and distances between the first star point and each of the at least one secondary RF chip are equivalent, and
a distance between the second star point and the primary RF chip and distances between the second star point and each of the at least one secondary RF chip are equivalent.

14. The RF device of claim 8, wherein:
the sine multi-chip package comprises at least one antenna electrically coupled to at least one of the primary RF chip or the at least one secondary RF chip, and
the at least one antenna is arranged in the electrical redistribution layer.

15. The RF device of claim 14, wherein the at least one antenna is arranged in a fan-out area of the electrical redistribution layer.

16. The RF device of claim 14, wherein the at least one antenna comprises at least one of a planar antenna or a slot antenna.

17. The RF device of claim 1, further comprising:
a printed circuit board, wherein the single multi-chip package is mounted on the printed circuit board, and wherein the printed circuit board is free of any signal transmission structures for transmitting RF signals.

18. The RF device of claim 1, further comprising:
a microcontroller chip configured to process signals transmitted to or received from the primary RF chip and the at least one secondary RF chip, wherein the microcontroller chip is arranged in the single multi-chip package.

19. The RF device of claim 1, wherein a footprint area of the single multi-chip package is smaller than 10 cm².

20. The RF device of claim 1, wherein each of the primary RF chip and the at least one secondary RF chip comprises a transceiver monolithic microwave integrate circuit (MMIC).

21. The RF device of claim 1, wherein the single multi-chip package comprises an embedded wafer level ball grid array (eWLB) package.

22. The RF device of claim 1, wherein the single multi-chip package comprises an antenna feed in package (AFIP).

23. The RF device of claim 22, wherein:
the AFIP comprises a first launcher structure coupled to a first RF port of the primary RF chip to transfer a first RF signal between the first RF port and a waveguide antenna, and
the AFIP comprises a second launcher structure coupled to a second RF port of a secondary RF chip of the at least one secondary RF chin to transfer a second RF signal between the second RF port and the waveguide antenna.

24. Method for manufacturing a radio frequency (RF) device, the method comprising:
collectively assembling a primary RF chip and at least one secondary RF chip in a single multi-chip package,
wherein the primary RF chip and the at least one secondary RF chip form a cascaded RF system.
